(19) United States
(12) Patent Application Publication
(10) Pub. No.: US 2015/0372124 A1
(43) Pub. Date: Dec. 24, 2015

(54) SEMICONDUCTOR DEVICE

(71) Applicant: KABUSHIKI KAISHA TOSHIBA, Tokyo (JP)

(72) Inventors: Yasuhiro ISOBE, Kanazawa Ishikawa (JP); Naoharu SUGIYAMA, Komatsu Ishikawa (JP)

(21) Appl. No.: 14/634,863

(22) Filed: Mar. 1, 2015

(30) Foreign Application Priority Data
Jun. 18, 2014 (JP) 2014-125531

(51) Int. Cl. H01L 29/778; H01L 29/36; H01L 29/20

(52) U.S. Cl. CPC H01L 29/778; H01L 29/2003; H01L 29/36

(57) ABSTRACT

A semiconductor device includes a first nitride semiconductor layer including carbon and having a first side and an opposing second side. The semiconductor device further includes an intrinsic nitride semiconductor layer on the first nitride semiconductor layer. A first side of the intrinsic semiconductor layer faces the second side of the first nitride semiconductor layer. The semiconductor device further includes a second nitride semiconductor layer including aluminum and disposed on a second side of the intrinsic nitride semiconductor layer opposite to the first nitride semiconductor layer. The first nitride semiconductor layer has a carbon distribution in which a concentration of carbon changes between a high concentration region and a low concentration region. In some embodiments, the high concentration region has a carbon concentration at least 100 times higher than the carbon concentration in the low concentration region.

### CROSS-REFERENCE TO RELATED APPLICATION

This application is based upon and claims the benefit of priority from Japanese Patent Application No. 2014-125531, filed Jun. 18, 2014, the entire contents of which are incorporated herein by reference.

### FIELD

Embodiments described herein relate generally to a semiconductor device.

### BACKGROUND

A nitride semiconductor is used in a power device to withstand to a high electric field as well as in a light-emitting device, and recently there has been a demand for devices having a high breakdown voltage.

### DESCRIPTION OF THE DRAWINGS

FIG. 1 is an example of a cross-sectional view schematically illustrating a semiconductor device according to a first embodiment.

FIG. 2A is an example of a view illustrating a specific example of a carbon [C] concentration distribution in a C—AlₓGa₁₋ₓN layer included in the semiconductor device illustrated in FIG. 1.

FIG. 2B is an example of a view illustrating another specific example of a carbon [C] concentration distribution in the C—AlₓGa₁₋ₓN layer included in the semiconductor device illustrated in FIG. 1.

FIG. 2C is an example of a view illustrating still another specific example of a carbon [C] concentration distribution in the C—AlₓGa₁₋ₓN layer included in the semiconductor device illustrated in FIG. 1.

FIG. 3A is an example of a view illustrating a specific example of a carbon [C] and aluminum [Al] concentration distribution in the C—AlₓGa₁₋ₓN layer included in the semiconductor device illustrated in FIG. 1.

FIG. 3B is an example of a view illustrating another specific example of a carbon [C] and aluminum [Al] concentration distribution in the C—AlₓGa₁₋ₓN layer included in the semiconductor device illustrated in FIG. 1.

FIG. 3C is an example of a view illustrating still another specific example of a carbon [C] and aluminum [Al] concentration distribution in the C—AlₓGa₁₋ₓN layer included in the semiconductor device illustrated in FIG. 1.

FIG. 4 is an example of a cross-sectional view schematically illustrating a semiconductor device according to a second embodiment.

FIG. 5A is an example of a cross-sectional view schematically illustrating a method for manufacturing the semiconductor device illustrated in FIG. 4.

FIG. 5B is an example of a cross-sectional view schematically illustrating a method for manufacturing the semiconductor device illustrated in FIG. 4.

### DETAILED DESCRIPTION

Exemplary embodiments provide a semiconductor device having a high breakdown voltage.

In general, according to one embodiment, a semiconductor device is provided. The semiconductor device includes a first nitride semiconductor layer containing carbon. The first nitride semiconductor layer has a first side and an opposing second side. The semiconductor further includes an intrinsic nitride semiconductor layer on the first nitride semiconductor layer. A first side of the intrinsic semiconductor layer faces the second side of the first nitride semiconductor layer. The semiconductor device further includes a second nitride semiconductor layer on a second side of the intrinsic nitride semiconductor layer opposite to the first nitride semiconductor layer and including aluminum. The first nitride semiconductor layer has a carbon distribution in which a concentration of carbon changes between a high concentration region and low concentration region. In some embodiments, the high concentration region has a carbon concentration at least 100 times higher than the carbon concentration in the low concentration region.

Hereinafter, some example embodiments will be described with reference to the drawings. In the drawings, the common components of these embodiments are denoted by the same reference numerals and overlapping description may be omitted where appropriate. Also, the accompanying drawings are schematic drawings that are simply intended to facilitate the understanding and the description of the exemplary embodiments, thus the accompanying drawings may depict elements or portions differing from the elements or portions of in actual apparatus in the shape, size, and/or relative size ratio.

In the disclosure, the term of “to stack layers” includes a case in which layers are stacked as directly contacting with each other as well as a case in which another layer that may not be shown or described is inserted between the layers described. The term “to be provided on” includes the case in which layers are directly provided on each other as well as the case in which another layer that may not be shown or described is inserted between the layers described.

(1) Semiconductor Device

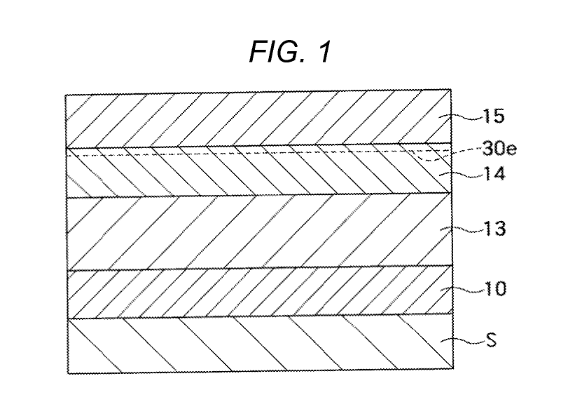

FIG. 1 is an example of a cross-sectional view schematically illustrating a semiconductor device according to a first embodiment. The semiconductor device according to a first embodiment includes a substrate S, a buffer layer 10, a C—AlₓGa₁₋ₓN layer 13, an intrinsic (i)-GaN layer 14, and an AlₓGa₁₋ₓN layer 15.

In this example, the substrate S is a Si substrate having a (111) plane. The thickness of the Si substrate is between, for example, about 500 μm and about 2 mm, such as between about 700 μm and about 1.5 mm. In addition, the substrate S may be a substrate on which a thin Si layer is stacked. When a substrate on which a thin Si layer is stacked is used, the thickness of the thin Si layer is between, for example, about 5 nm and about 500 nm. However, the substrate S is not limited to a Si substrate and other substrates, such as a SiC substrate, a sapphire substrate, or a GaN substrate may be used.

Here, the buffer layer 10 is an AlN layer which is provided on the substrate S as contacting with the substrate S. The thickness of the AlN layer 10 is between, for example, about 50 nm and about 500 nm, such as between about 100 nm and about 300 nm. In some embodiments, a multilayer film having a superlattice structure may be used instead of the buffer layer 10. Here, the term of “superlattice structure” refers to a structure obtained by alternately stacking multiple pairs, for example, such as 20 pairs of an AlN layer having a thickness of about 5 nm with a GaN layer having a thickness of about 20 nm.

Furthermore, in some embodiments an Al_{y}Ga_{1-y}N layer (0<y<1) (not shown) may be interposed between the AlN layer 10 and the substrate S as contacting with the AlN layer 10 on the side of the AlN layer 10 facing the substrate S depending on the layer thickness of the whole semiconductor device and the design of the semiconductor device. In this case, the thickness of the Al_{y}Ga₁₋₇N layer (0<y<1) is between, for example, about 100 nm and about 1,000 nm.

The C—AlₓGa₁₋ₓN layer 13 is an AlₓGa₁₋ₓN layer (0≦x<0.01) containing carbon [C], and the layer 13 is provided on the side of the buffer layer 10 opposite to the substrate S. The thickness of the C—AlₓGa₁₋ₓN layer 13 is between, for example, about 100 nm and about 10 μm, and an average concentration of carbon [C] contained in the C—AlₓGa₁₋ₓN layer 13 is between, for example, about 1×10¹⁶ cm⁻³ and about 3×10¹⁹ cm⁻³. The minimum concentration of carbon [C] in a region of the C—AlₓGa₁₋ₓN layer 13 is about 1×10¹⁰ cm⁻³ and the maximum concentration thereof in a different region of the C—AlₓGa₁₋ₓN layer 13 is about 5×10¹⁹ cm⁻³. When carbon [C] is added into the AlₓGa₁₋ₓN layer, a leakage current may be reduced and thus the insulating resistance of the whole semiconductor device increases. Therefore, a high breakdown voltage may be achieved. The C—AlₓGa₁₋ₓN layer 13 corresponds to, for example, a first nitride semiconductor layer.

The i-GaN layer 14 is provided on the side of the C—AlₓGa₁₋ₓN layer 13 opposite to the buffer layer 10. The thickness of the i-GaN layer 14 is between, for example, about 0.5 μm and about 3 μm, and the impurity concentration of all of carbon [C], oxygen [O], and silicon [Si] in the i-GaN layer 14 is less than about 3×10¹⁷ cm⁻³. In the embodiment, the i-GaN layer 14 corresponds to, for example, an intrinsic nitride semiconductor layer and the side opposite to the buffer layer 10 corresponds to a first side.

The AlₓGa₁₋ₓN layer 15 is formed on the side of the i-GaN layer 14 opposite to the C—AlₓGa₁₋ₓN layer 13 and includes non-doped or n-type AlₓGa₁₋ₓN (0<x≦1). A two-dimensional electron gas (2DEG) 30e is generated in the vicinity of an interface between the i-GaN layer 14 and the AlₓGa₁₋ₓN layer 15 inside the i-GaN layer 14. Thus, the i-GaN layer 14 functions as a channel. In the embodiment, the AlₓGa₁₋ₓN layer 15 corresponds to, for example, a second nitride semiconductor.

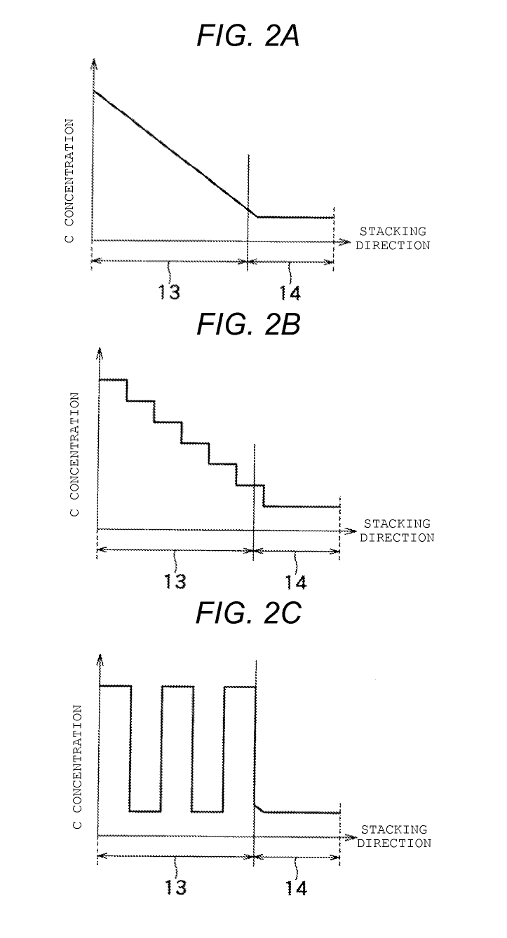

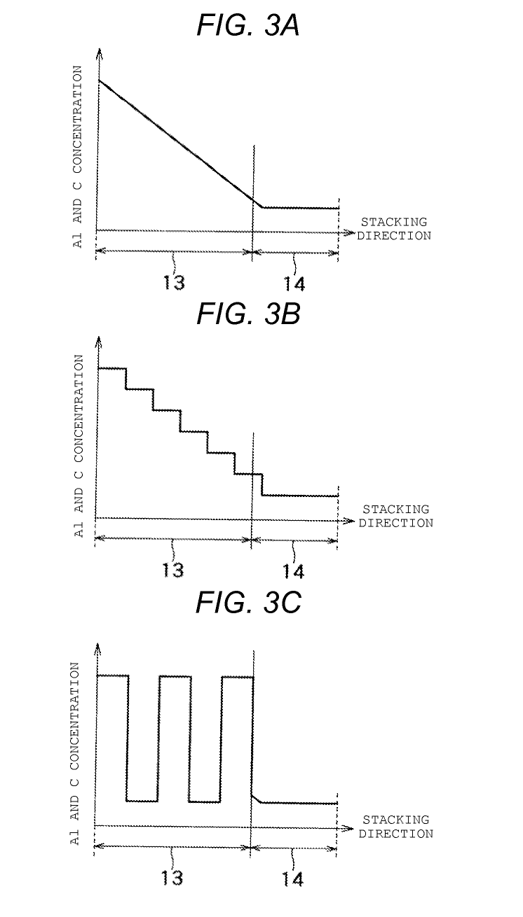

Next, specific configurations of the C—AlₓGa₁₋ₓN layer 13 will be described with reference to FIGS. 2A to 3C.

The concentration distribution of the added carbon [C] in the C—AlₓGa₁₋ₓN layer 13 is not uniform and changes in the thickness direction thereof, that is, in a direction in which the buffer layer 10, the C—AlₓGa₁₋ₓN layer 13, the i-GaN layer 14, and the AlₓGa₁₋ₓN layer 15 are stacked on the substrate S.

Specific examples of the carbon [C] concentration change in C—AlₓGa₁₋ₓN layer 13 are illustrated in FIGS. 2A to 2C. In the example illustrated in FIG. 2A, the concentration of carbon [C] changes at a predetermined ratio from the side of the C—AlₓGa₁₋ₓN layer 13 close to the buffer layer 10 to the side close to the i-GaN layer 14. In some embodiments, the rate of change of the concentration of carbon can be constant across C—AlₓGa₁₋ₓN layer 13. In the example illustrated in FIG. 2B, the concentration of carbon [C] changes stepwise from the side of the C—AlₓGa₁₋ₓN layer 13 close to the buffer layer 10 to the side close to the i-GaN layer 14.

In FIGS. 2A and 2B, as a change state of the concentration of carbon [C], examples in which the concentration of carbon [C] is gradually reduced from the side of the C—AlₓGa₁₋ₓN layer 13 facing the buffer layer 10 to the side facing the i-GaN layer 14 are illustrated. This is because in a case when the carbon [C] concentration distribution is uniform, the quality of a GaN crystal can be deteriorated. For example, a GaN layer can be deteriorated towards the upper side of the layer, that is, the side of the layer facing away from the substrate. This deterioration can occur when epitaxial growth layers are used to format least some of the layers. The quality deterioration of the GaN crystal also induces a phenomenon that increases the resistance during the device operation (i.e., current collapse).

A Si substrate can be used as the substrate S. When the concentration of carbon [C] is uniform across the thickness of the C—AlₓGa₁₋ₓN layer 13, compressive stress is not easily applied during the epitaxial growth. However, compressive stress is easily applied when the concentration of carbon [C] is reduced from the side of the C—AlₓGa₁₋ₓN layer 13 facing the buffer layer 10 to the side facing the i-GaN layer 14, and as a result, it is possible to obtain a wafer which is crack-free and has an upward convex shape (a convex bow).

However, the concentration of carbon in the C—AlₓGa₁₋ₓN layer 13 does not need to be limited to configurations in which the concentration of carbon only decreases from the side of the C—AlₓGa₁₋ₓN layer 13 facing the buffer layer 10 to the side of the C—AlₓGa₁₋ₓN layer 13 facing the i-GaN layer 14. For example, the concentration of carbon can decrease and increase across different regions of the C—AlₓGa₁₋ₓN layer 13. In one embodiment as illustrated in FIG. 2C, the carbon [C] concentration in the C—AlₓGa₁₋ₓN layer 13 can change in a comb-teeth pattern. The C—AlₓGa₁₋ₓN layer 13 is not limited to these examples and for example, a high concentration region and a low concentration region (in which, for example, the addition of carbon [C] is intentionally stopped) may be repeated from the side facing the buffer layer 10 to the side facing the i-GaN layer 14. In this case, for example, the thickness of the C—AlₓGa₁₋ₓN layer 13 is between about 100 nm and about 10 μm, and the minimum concentration of carbon [C] in a region of the C—AlₓGa₁₋ₓN layer 13 is about 1×10¹⁰ cm⁻³ and the maximum concentration thereof in a different region of the C—AlₓGa₁₋ₓN layer 13 is about 5×10¹⁹ cm⁻³. The number of repetitions of the high concentration region and the low concentration region (amplitude number) is 5 times at minimum (e.g., see FIG. 2C with 3 high concentration regions and 2 low concentration regions). When the thickness of the C—AlₓGa₁₋ₓN layer 13 is Y μm, the amplitude number is between 10Y and 1000Y. Also in the embodiment illustrated in FIG. 2C, since the carbon [C] in the high concentration region is diffused to the low concentration region, the average carbon concentration is between, for example, 1×10¹⁶ cm⁻³ and 3×10¹⁹ cm⁻³ and thus it is possible to achieve a device having a high breakdown voltage. As described above, when the nitride semiconductor epitaxial growth layer to which carbon [C] is added uniformly across the thickness of the C—AlₓGa₁₋ₓN layer 13, the crystal quality is deteriorated. However, when a low concentration region layer is provided between high concentration regions as shown in FIG. 2C, it is possible to suppress a deterioration in the crystal quality and also possible to suppress a current collapse phenomenon.

In addition, the aluminum [Al] composition ratio (that is, the value of x in C—AlₓGa₁₋ₓN layer 13) may be changed as well as the concentration of carbon [C] in the C—AlₓGa₁₋ₓN layer 13. The profile of the change of the aluminum [Al] composition ratio can follow the profile of the change of the concentration of carbon [C] as illustrated in FIGS. 3A to 3C. By stating that the profile of the aluminum concentration follows the profile of carbon concentration, it is meant, for example, that if the carbon concentration is increasing along the thickness dimension of a first region, then the aluminum composition is also increasing along the thickness dimension in that first region. It is not required that the concentration of carbon and the concentration of aluminum match at certain points along any dimension. The profile of the change in the concentration of carbon [C] and the composition ratio of aluminum [Al] is not limited to these examples provided above and further embodiments are within the scope of this disclosure. When the composition ratio of aluminum [Al] changes in the stacking direction, for example, from the side facing the buffer layer 10 to the side facing the i-GaN layer 14 in this manner, the concentration of carbon [C] can be easily controlled and thus a high quality crystal may be obtained.

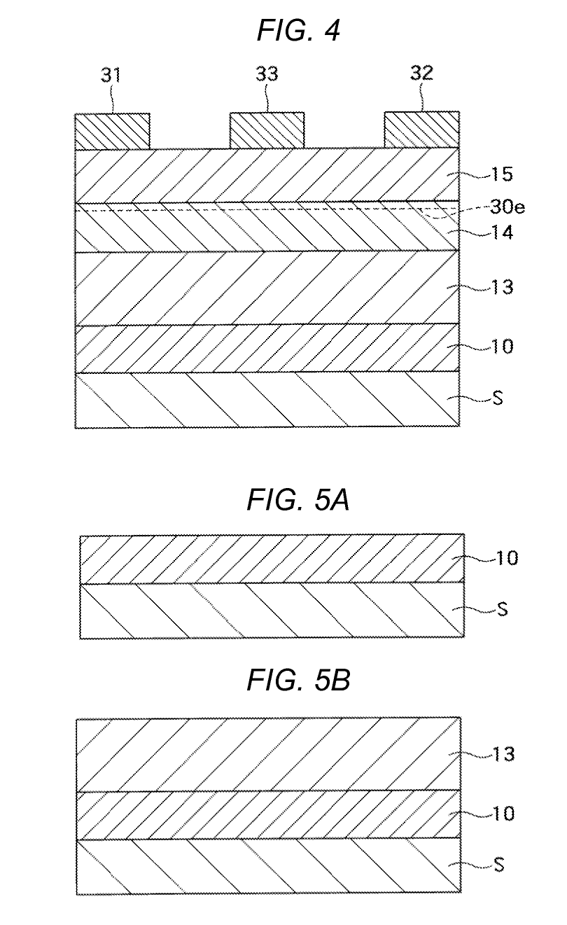

FIG. 4 is an example of a cross-sectional view schematically illustrating a configuration of a semiconductor device according to a second embodiment.

The semiconductor device according to the second embodiment can be used for a high electron mobility transistor (HEMT) such that electrodes 31 to 33 are further provided in the semiconductor device illustrated in FIG. 1.

Specifically, the semiconductor device illustrated in FIG. 4 includes, in addition to the semiconductor device in which the substrate S, the buffer layer 10, the C—AlₓGa₁₋ₓN layer 13, the i-GaN layer 14, and the AlₓGa₁₋ₓN layer 15 are stacked in this order, a source (or drain) electrode 31, a drain (or source) electrode 32, and a gate electrode 33.

The source (or drain) electrode 31 and the drain (or source) electrode 32 are provided so as to be separated from each other on the side of the AlₓGa₁₋ₓN layer 15 opposite to the i-GaN layer 14 and are respectively formed so as to be in an ohmic contact with the AlₓGa₁₋ₓN layer 15. The source (or drain) electrode 31 and the drain (or source) electrode 32 correspond to, for example, a first electrode and a second electrode, respectively.

The gate electrode 33 is formed on the side of the AlₓGa₁₋ₓN layer 15 opposite to the i-GaN layer 14 so as to be interposed between the source (or drain) electrode 31 and the drain (or source) electrode 32. In the embodiment, the gate electrode 33 corresponds to, for example, a control electrode.

Although not specifically depicted in FIG. 4, an insulating film may be formed in the regions on the AlₓGa₁₋ₓN layer 15 between these electrodes 31 to 33. Furthermore, a gate insulating film (not shown) is interposed between the gate electrode 33 and the AlₓGa₁₋ₓN layer 15 to form a metal-insulator-semiconductor (MIS) structure.

In the semiconductor devices having the C—AlₓGa₁₋ₓN layer 13 in which the concentration of carbon [C] or the concentration of carbon [C] and aluminum [Al] changes in the stacking direction a high breakdown voltage is provided.

(2) Method for Manufacturing Semiconductor Device

Next, an example of a method for manufacturing a semiconductor device illustrated in FIG. 4 will be described with reference to FIGS. 5A and 5B.

First, as illustrated in FIG. 5A, the buffer layer 10 is formed on the substrate S by low temperature growth using a known method.

Next, the GaN crystal is epitaxially grown on the side of the buffer layer 10 opposite to the substrate S by metal organic chemical vapor deposition (MOCVD) while being doped with carbon [C]. As a doping gas, for example, acetylene (C₂H₂) or carbon tetrabromide (CBr₄) is used.

In order to increase the concentration of carbon [C] in the epitaxially growing GaN crystal, methods that can be used include (a) lowering the growth chamber pressure, (b) decreasing a ratio of a V-group element material to a III-group element (N/Ga in the example), and/or (c) lowering the growth chamber temperature, and the like.

Here, when the GaN crystal is epitaxially grown while the doping gas containing a predetermined concentration of carbon [C] is supplied, the supplied carbon [C] inhibits epitaxial growth if an excessive amount of carbon [C] is supplied instantaneously. Thus, there is a problem that the quality of the GaN crystal may be deteriorated. Particularly, when the epitaxial growth layer of GaN is formed to be thick, there is also a problem that the quality of the GaN crystal may be deteriorated toward the upper layer side, that is, the side of the layer facing away from the substrate. In addition, as described above, when the GaN crystal is grown on the Si substrate, a lattice constant of GaN to which a high concentration of carbon [C] is added does not have an ideal value and thus compressive stress during the growth is not easily applied. Therefore, there is a problem that a wafer which is crack-free and has an upward convex shape (a convex bow) may not be obtained.

In order to solve these problems, for example, as illustrated in FIGS. 2A to 2C, the amount of the doping gas, the growth temperature, and the pressure are controlled according to a desired carbon [C] concentration distribution. However, even when a combination of these parameters is optimized, there is still a problem in the crystal quality of the GaN layer.

In the examples described above, by utilizing the property that the nitride semiconductor containing Al easily incorporates other impurities, aluminum [Al] is doped during the epitaxial growth of the GaN crystal. The amount of aluminum [Al] to be doped can be less than about 1%. Accordingly, it is possible to increase the amount of the incorporated carbon [C] without a strong influence on the lattice constant, the crystal quality, and the growth rate of GaN. As a result, the C—AlₓGa₁₋ₓN layer 13 to which carbon [C] is added is formed as illustrated in FIG. 5B. As in the example described above, when aluminum [Al] is doped, the value of x in AlₓGa₁₋ₓN is in a range of 0<x<0.01.

To further increase the amount of the incorporated carbon [C], the amount of carbon to be supplied can be increased by using the following reaction formula (1), which uses trimethylaluminum Al(CH₃)₃ (also referred to as “TMAl”). Reaction Formula (1):

Ga(CH₃)₃+Al(CH₃)₃+NH₃=GaN,AlN,+H,C

As described above, the amount of carbon [C] to be supplied may also be increased by increasing the amount of a III-group raw material.

Furthermore, as illustrated in FIGS. 3A to 3C, not only the amount of carbon [C] to be doped but also the amount of aluminum [Al] to be doped may be changed. Thus, there are numerous options of the combination of the raw material composition in AlGaN and the concentration distribution of carbon [C] to be doped.

Then, by a known method, the i-GaN layer 14 and the AlₓGa₁₋ₓN layer 15 are sequentially formed on the side of the C—AlₓGa₁₋ₓN layer 13 opposite to the buffer layer 10 and the electrodes 31 and 32 (to become a source or a drain) are further formed so as to be in an ohmic contact with the AlₓGa₁₋ₓN layer 15. The gate electrode 33 is formed between the electrodes 31 and 32 on the side of the AlₓGa₁₋ₓN layer 15 opposite to the i-GaN layer 14 and thus the semiconductor device illustrated in FIG. 4 is provided.

According to the above-described method for manufacturing the semiconductor device, the concentration of carbon [C] or the concentration of carbon [C] and aluminum [Al] is changed during the epitaxial growth of the GaN crystal, and thus, a similar leak current reduction effect may be obtained as in a case in which carbon [C] is continuously doped in a predetermined concentration. In addition, a good crystal quality may be obtained. Furthermore, when the C—AlₓGa₁₋ₓN layer 13 is formed on the Si substrate, an upward convex shape (a convex wafer bow) may be obtained. Accordingly, it is possible to provide a semiconductor device having a high breakdown voltage.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first nitride semiconductor layer containing carbon, the first nitride semiconductor layer having a first side opposite a second side;
an intrinsic nitride semiconductor layer on the first side of the first nitride semiconductor layer; and
a second nitride semiconductor layer on the intrinsic nitride semiconductor layer opposite to the first nitride semiconductor layer and including aluminum,
wherein the first nitride semiconductor layer has a carbon distribution along a thickness direction from the second side to the first side in which a concentration of carbon changes from a high concentration region to a low concentration region.

2. The semiconductor device according to claim 1, wherein the high concentration region has a carbon concentration at least 100 times higher than the carbon concentration in the low concentration region.

3. The semiconductor device according to claim 1, wherein the concentration of carbon in the first nitride semiconductor layer decreases from the high concentration region to the low concentration with a substantially constant rate along the thickness direction.

4. The semiconductor device according to claim 1, wherein the concentration of carbon in the first nitride semiconductor layer is reduced from the high concentration region to the low concentration region in a stepwise pattern along the thickness direction.

5. The semiconductor device according to claim 1, wherein the first nitride semiconductor layer includes high concentration regions and low concentration regions disposed in an alternating order along the thickness direction.

6. The semiconductor device according to claim 5, wherein when a thickness of the first nitride semiconductor layer is Y μm (0.1≦Y≦10), a number of repetitions of the high concentration region and the low concentration region is between 10Y and 1,000Y.

7. The semiconductor device according to claim 1, wherein the concentration of carbon in the high concentration region is greater than the concentration of carbon in the low concentration region by a factor of at least 1×10⁶.

8. The semiconductor device according to claim 1, wherein the first nitride semiconductor layer is carbon doped aluminum gallium nitride and a combined concentration of aluminum and carbon in the first nitride semiconductor layer varies along the thickness direction.

9. The semiconductor device according to claim 1, further comprising:
a first electrode and a second electrode on the second nitride semiconductor layer on a side opposite the intrinsic nitride semiconductor layer, the first and second electrodes spaced from each other; and
a control electrode on the second nitride semiconductor layer between the first electrode and the second electrode.

10. A semiconductor device, comprising:
a first nitride semiconductor layer including aluminum and carbon, the first nitride semiconductor layer having a first side and an opposing second side;
an intrinsic nitride semiconductor layer on the first nitride semiconductor layer, wherein a first side of the intrinsic semiconductor layer faces the second side of the first nitride semiconductor layer; and
a second nitride semiconductor layer on a second side of the intrinsic nitride semiconductor layer opposite to the first nitride semiconductor layer and including aluminum,
wherein the first nitride semiconductor layer has a carbon distribution and an aluminum distribution in which a concentration of carbon and a composition ratio of aluminum both change along a thickness direction from the second side of the first nitride semiconductor layer to the second side of the first nitride semiconductor layer from a high level to a low level.

11. The semiconductor device according to claim 10, wherein the concentration of carbon and the composition ratio of aluminum in the first nitride semiconductor layer is reduced from the high level to the low level at a substantially constant rate along the thickness direction.

12. The semiconductor device according to claim 10, wherein the first nitride semiconductor layer is carbon doped aluminum gallium nitride and a composition ratio of gallium in first nitride semiconductor layer is at least 90 times higher than the composition ratio of aluminum in the first nitride semiconductor layer.

13. The semiconductor device according to claim 10, further comprising:
a first electrode and a second electrode on the second nitride semiconductor layer on a side opposite the intrinsic nitride semiconductor layer, the first and second electrodes spaced from each other; and
a control electrode on the second nitride semiconductor layer between the first electrode and the second electrode.

14. The semiconductor device according to claim 10, wherein the concentration of carbon and the composition ratio of aluminum in the first nitride semiconductor layer is reduced from the high level to the low level in a stepwise pattern along the thickness direction.

15. The semiconductor device according to claim 10, wherein the first nitride semiconductor layer includes at least three high concentration regions in which the concentration of carbon and the composition ratio of aluminum is at the high level and at least two low concentration regions in which the concentration of carbon and the composition ratio of aluminum is the low level, and the high and low concentration regions are disposed in alternating order along the thickness direction.

16. The semiconductor device according to claim 15, wherein the concentration of carbon in the high concentration regions is higher than the concentration of carbon in the low concentration region by a factor of at least 1×10⁶.

17. The semiconductor device according to claim 10, wherein the high level of the concentration of carbon and the is about 5×10¹⁹ cm⁻³, and the low level of the carbon concentration is about 1×10¹⁰ cm⁻³.

18. A semiconductor device, comprising:
a first nitride semiconductor layer including carbon, the first nitride semiconductor having a first side and an opposing second side;
an intrinsic nitride semiconductor layer on the first nitride semiconductor layer, wherein a first side of the intrinsic semiconductor layer faces the second side of the first nitride semiconductor layer; and
a second nitride semiconductor layer on a second side of the intrinsic nitride semiconductor layer opposite to the first nitride semiconductor layer and including aluminum,
wherein the first nitride semiconductor layer has a carbon distribution in which a first concentration of carbon and a second concentration of carbon lower than the first concentration are repeated in a thickness direction from the first side to the second side of the first nitride semiconductor layer, wherein the first nitride semiconductor layer includes at least two regions of the first concentration and at least two regions of the second concentration arranged in an alternating pattern.

19. The semiconductor device according to claim 18, further comprising:
a first electrode and a second electrode on the second nitride semiconductor layer on a side opposite the intrinsic nitride semiconductor layer, the first and second electrodes spaced from each other; and
a control electrode on the second nitride semiconductor layer between the first electrode and the second electrode.

20. The semiconductor device according to claim 18, wherein a thickness of the first nitride semiconductor layer is Y μm (0.1≦Y≦10), and a number of repetitions of the first concentration and the second concentration is between 10Y and 1,000Y.
